(19) United States
(12) Patent Application Publication
(10) Pub. No.: US 2009/0192742 A1
(43) Pub. Date: Jul. 30, 2009

(54) PROCEDURE FOR INCREASING SPECTRUM ACCURACY

(76) Inventor: Mensur Omerbashich, Sarajevo (BA)

Correspondence Address: MENSUR OMERBASCHICH, Trg solidarnosti 3/2, Sarajevo, 71000, BA

(21) Appl. No.: 12/022,409

(22) Filed: Jan. 30, 2008

(51) Int. Cl. G01R 23/16

(52) U.S. Cl. 702/76

(57) ABSTRACT

The method patented enables increase in reliability of periodicity estimates, and consequently of the natural band (of an object; of a body; of a system; etc.) definition too. The patented method is based on the least squares spectral analysis (LSSA) method. The LSSA has been proven over the past thirty years to be fully able of replacing the Fourier and Fourier-based spectral analysis methods (as the most used methods of spectral analysis in all sciences). The here patented method then uses this known feature of the LSSA as a reliable periodicity estimator, and expands its application by claiming that periodicity estimates generally (in all sciences and in all situations) could be improved by removing a number of measurements from the original dataset. Thus, by removing the least reliable (where ‘least’ is according to some, e.g., well-known, criteria) measurements from the dataset of interest, one can estimate periodicities in any (complete or not) type of a numerical record to the logically greatest extent possible.

### BACKGROUND OF THE INVENTION

This is a patent of most general utility. It contains a procedure for increasing the accuracy of spectral analyses in general. This invention has direct applicability to most industries such as, but not limited to (NTIS specification in alphabetical order): Biology, Chemistry, Earth Sciences, Economy, Electrotechnology, Genetics, Materials Sciences, Mathematical Sciences, Medicine, Natural Resources, Oil Exploration, and Physics.

The basis for this claim is in the following: many spectral analyses can be made more accurate by (1) classifying the measurements before processing them, according to their quality and reliability; and (2) subsequently excluding the less reliable measurements from the input record and analyzing the remaining data in the least squares spectral analysis (LSSA).

After up to 50% of least-reliable variations in a sampled record are excluded from the record, the expected quantifiable increase in reliability of estimated periodicity in that record increases up to 50% compared to reliability of periods obtained by classically applied methods, e.g., Fourier's.

As a proof of the here patented procedure, I was able to show, in comparison with Fourier approach, that the ratio between the Earth's total kinetic energy v. the Earth's total seismic energy (lithospheric portion of kinetic energy) is constant everywhere throughout the Earth. For this, most geophysical records were inherently incomplete. Thus, the research results, partially presented in Omerbashich (2003) (unpublished; copyrights reserved entirely), indicated the correctness of the here patented approach in a geophysical setup. Physical meaning for those results has been elucidated in Omerbashich (2007). Since the Earth is a most general closed mechanical system of all, my finding then applies to any physical field too. By extension, the identical principle applies to any non-physical (say, abstract) system as well, such are systems defined and studied in disciplines of economy/finance, genetics, medicine, etc.

Essentially, the idea is to increase the signal-to-noise-ratio by eliminating the largest suppliers of noise into the system. Thanks to accuracy of the least squares spectral analysis, which remains the same for losses of up to 50% of data (Omerbashich, 2003), such a removal of less reliable values not only improves the signal v. noise resolution, but also prevents the generation (by way of less reliable values) of artificial periodicities, as well as lessens the deformation of existing periodicities.

Thus, I discovered a way how to increase the accuracy of spectral analyses in general, in an undemanding manner using readily-available algorithms of the least-squares spectral analysis (see, e.g., Press at al. 2003), which have been applied in various disciplines over the past 35 years.

### BRIEF SUMMARY OF THE INVENTION

A data-manipulation procedure for increasing the accuracy of spectral analyses in general.

### DETAILED DESCRIPTION OF THE INVENTION

The least squares spectral analysis—LSSA by Vani\check{c}ek (1969, 1971) is a least squares estimation method for computing variance- or power-spectra from any type of numeric or quasi-numeric (originally non-numeric) record of any size and composition. Superiority of optimization in the Euclidean sense offers numerous advantages over using the classical Fourier Spectral Analysis (FSA) for the same purpose (Press et al., 2001). Fourier spectral analysis and its derivative methods are by far the most used techniques of spectral analysis in all sciences.

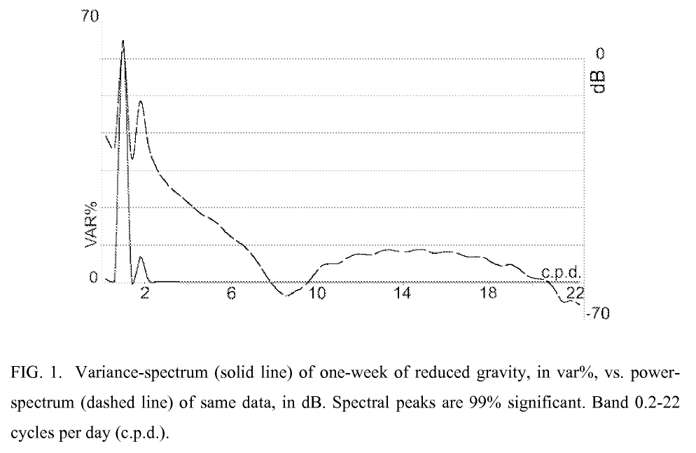

The most important LSSA advantage is in its blindness to the existence of gaps in records: least-squares spectral analyses do not require uniformly sampled data unlike the Fourier spectral analysis and its derivative methods. Neither preprocessing nor post-processing to artificially enhance either the time series (by padding the record with invented data) or its spectrum (by stacking or otherwise augmenting the spectrum), respectively, are required when LSSA is used. Furthermore, the output variance spectrum possesses linear background, i.e., the spectrum is generally zero everywhere except for the periodicities; see FIG. 1. This gives a unique definition and full meaning to the spectral magnitudes within the band of computation.

Unlike any known methods of spectral analysis, the LSSA can be used with virtually any set of numerical or quasi-numerical (originally non-numeric) data, complete or gapped, thus making it the technique of preference in practically all sciences that deal with inherently discontinuous records, such as: biotechnology, genetics, genetic engineering, chemistry, chemical engineering, physics, geophysics, electronics, electrical engineering, medicine, and medical and diagnostic equipment manufacturing.

Potential benefits from the increased accuracy of spectral analyses (of virtually any record) are tremendous, and are summarized as the common bettering of life quality in general, particularly in economically underdeveloped areas of the world, e.g., by providing more efficient tools that rely upon more stable electronic and industrial systems, low-cost medical services and lab testing, and increase in standard of living in general.

The least-squares spectral estimation is part of the series of least-squares estimation theories started once by Gauss and Legendre, and completed by Vanicek. The LSSA has been developed for the needs of, and subsequently used to a great success in: astronomy, geodesy and geophysics, finance, mathematics, medicine, computing science etc. A test of LSSA on synthetic data can be found in Omerbashich (2003), together with a list of references.

The patented procedure consists of two steps:
1. Weigh each value of raw (noise inclusive) data composed of sampled variations, according to each value's a-priori error assessments based upon some usually applied (generally accepted) pre-selected criteria;
2. Purify the data by removing up to 50% of least-reliable data from the dataset prior to feeding the data into the least-squares spectral analysis algorithm, to produce the output variance-spectrum or the output power-spectrum.

FIG. 1 demonstrates the validity of LSSA as a uniform descriptor of noise levels; having linear (here: zero-var %-level) background over a band of interest everywhere except for statistically significant peaks.

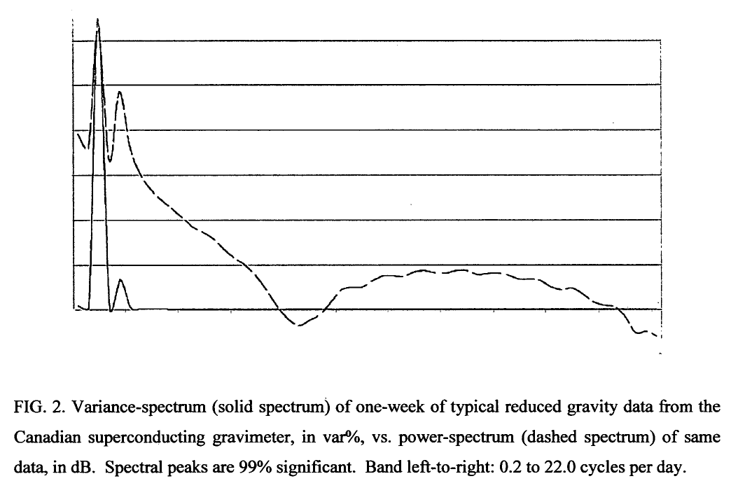

FIG. 2 shows validity of arbitrary purification (removal of data) for achieving a substantial improvement to the periodicity estimate (here: of the start-end of the natural band of Earth eigenfrequencies). In order to estimate the grave mode of the Earth total-mass oscillation, broadband recordings with superconducting gravimeter (SG) at Cantley, Que., of gravity during three greatest shallow (focal depth below 10 km) earthquakes from the 1990-ies, were used. Thanks to LSSA-unique ability to process gapped records, differences are sought between the spectra of gravity recordings without gaps v. the same recordings with gaps artificially introduced. New 5, 21, and 53 filter-step-long (a step equaling to 8 sec) gaps are thus introduced in the three records, respectively, where the order of earthquakes was random. By observing the differences between the LSSA spectra of complete v. incomplete records, the first instance when this difference reaches zero value is sought for. Since both the complete and the incomplete records described the same instance and the same location when and where the same field (in this example: the Earth gravity field) was sampled during the three energy emissions, it is precisely this value that marks the beginning of the Earth's natural band of oscillation.

To prove that set-up correct, I show that the more gaps the record has indeed means the more pronounced impact of the non-natural information onto the spectra too. FIG. 2 shows this: more gaps results in a clearer distinction between the natural and non-natural bands. Thus the grave mode (i.e., the most natural period) of the Earth total-mass oscillation was measured as (Omerbashich, 2003): Tₒ′=3445 s±0.35%, where the uncertainty is based on 1000 pt spectral resolution. This is in agreement with the seminal paper by Benioff (1958).

Since only raw data are required for the here described data preparation procedure, and subsequently for the least squares spectral analysis as well, the patented procedure itself is justified by the above described positive result as stemming from the most natural criterion of all: the criterion of using raw (unaltered and gapped) data rather than artificially (“inside the lab”) edited datasets, usually created by adding or otherwise augmenting the data in order to make input records artificially equispaced (padded) and thereby fit for feeding into a selected data processing algorithm such as the Fourier spectral analysis method and its derivatives.

The above claims are also supported by the included references.

### REFERENCES

Benioff, H. Long waves observed in the Kamchatka earthquake of Nov. 4, 1952. J. Geoph. Res. 63, 589-593 (1958).
Omerbashich, M. Earth-model Discrimination Method. Ph.D. thesis, pp. 129. Dept of Geodesy, U of New Brunswick, Fredericton, Canada. Unpublished; copyrights reserved entirely (2003).
Omerbashich, M. Magnification of mantle resonance as a cause of tectonics. Geodinamica Acta (European J of Geodynamics) 20, 6: 369-383 (2007).
Vanicek, P. Approximate Spectral Analysis by Least-squares Fit. Astrophysics and Space Science, 4: 387-391 (1969).
Vani\check{c}ek, P. Further development and properties of the spectral analysis by least-squares fit. Astrophysics and Space Science, 12: 10-33 (1971).
Press, W. H., Teukolsky, S. A., Vetterling, W. T. & Flannery B. P. Numerical Recipes. Cambridge University Press (2003).
Omerbashich, M. A Gauss-Vani\check{c}ek Spectral Analysis of the Sepkoski Compendium: No New Life Cycles. Computing in Science and Engineering 8 (4): 26-30, American Institute of Physics & IEEE (2006).
Van Camp, M. Measuring seismic normal modes with the GWRC021 superconducting gravimeter. Phys. Earth Planet. Interiors 116 (1-4): 81-92 (1999).
Zharkov, V. N., S. M. Molodensky, A. Brzeziński, E. Groten, and P. Varga. The earth and its rotation: low frequency geodynamics. Herbert Wichmann Verlag, Hüthig GmbH, Heidelberg, Germany (1996).

Having described my invention, what I claim is:

1. By using the described procedure (i.e., by the removal of up to 50% of the least reliable data values), the spectrum of a input numerical dataset can be made up to 50% more reliable when compared to other procedures, notably those based on and required for the Fourier spectral analysis and its derivatives as the currently most used of all spectral analysis methods in all sciences.

2. The patented data processing approach (to preparing data for feeding data into the spectral analysis algorithm) represents the simplest approach of all for achieving the most reliable results achievable using any spectral analysis method or derivative.

3. The spectrum obtained in the here described manner, in both its periodicity-estimates as well as spectral-magnitudes advantages (over the Fourier method and its derivatives), when applied onto problems faced with in physical sciences, enable most rigorous spectral analyses.
